(19) United States
(12) Patent Application Publication
(10) Pub. No.: US 2026/0180472 A1
(43) Pub. Date: Jun. 25, 2026

(54) MEMS CONTROLLER AND MEMS DEVICE

(71) Applicant: AAC Kaitai Technologies (Wuhan) CO., LTD., Wuhan (CN)

(72) Inventors: Linxin Zhang, Wuhan (CN); Qiang Dan, Wuhan (CN); Yang Li, Wuhan (CN)

(21) Appl. No.: 19/322,668

(22) Filed: Sep. 8, 2025

Related U.S. Application Data
(63) Continuation of application No. PCT/CN2024/141906, filed on Dec. 24, 2024.

(51) Int. Cl. H02N 1/00; B81B 7/00; F28F 3/12; H04R 19/02

(52) U.S. Cl. CPC H02N 1/006; B81B 7/0061; F28F 3/12; B81B 2201/0257; B81B 2203/0118; B81B 2203/0307; H04R 19/02; H04R 2201/003

(57) ABSTRACT

Provided are a MEMS controller and a MEMS device, including: at least one control unit including: two adjacent anchor structures with a first gap therebetween; and cantilever beam structures respectively corresponding to the two anchor structure, a first end of each cantilever beam structure being located at a top surface of the anchor structure corresponding thereto, and second ends of two adjacent cantilever beam structures directly facing each other and forming a second gap therebetween; and an encapsulation structure including a bottom plate, a side plate and a top plate connected in sequence, the bottom plate directly facing the top plate. The bottom plate is located at the bottom surface of the anchor structure and provided with a first flow channel port. The top plate is spaced from the top surfaces of the two cantilever beam structures and provided with a second flow channel port.

### TECHNICAL FIELD

The present disclosure relates to the field of controllers and, in particular, to a MEMS controller and a MEMS device.

### BACKGROUND

A Micro-Electro-Mechanical System (MEMS), also known as micro-electro-mechanical system or microsystem, refers to a high-tech device with a size of several millimeters or even smaller, and its internal structure is generally in a micrometer level or even a nanometer level. The MEMS is an independent intelligent system developed based on microelectronics technology (semiconductor manufacturing technology), integrating technologies such as lithography, corrosion, thin film, LIGA, silicon micromachining, non-silicon micromachining and precision machining.

The MEMS technology is widely used in various fields, including but not limited to: a consumer electronics product, such as a micro speaker and a MEMS microphone. Such a product is widely used in laptops, smart phones and other devices due to its advantages such as a small size, low power consumption and batch manufacturing.

At present, a MEMS controller needs to be provided to control unidirectional movement of a fluid.

### SUMMARY

The present disclosure provides a MEMS controller and a MEMS device, which can at least control unidirectional movement of a fluid.

In an aspect, an embodiment of the present disclosure provides a MEMS controller, including: at least one control unit, the at least one control unit including: two anchor structures, a first gap being formed between two adjacent anchor structures, and each of the two anchor structures including a bottom surface and a top surface opposite to each other; and two cantilever beam structures respectively corresponding to the two anchor structures, each of the two cantilever beam structures including a first end and a second end opposite to each other, the first end of each of the two cantilever beam structures being located at the top surface of the corresponding anchor structure, and the second ends of the two cantilever beam structures directly facing each other and forming a second gap therebetween; and an encapsulation structure including a bottom plate, a side plate and a top plate connected in sequence, the bottom plate facing the top plate, and the side plate connecting the bottom plate and the top plate. The bottom plate is located at the bottom surfaces of the two anchor structures, the bottom plate is provided with a flow channel port penetrating through the bottom plate, the first flow channel port corresponds to the control unit, the first flow channel port is in communication with the first gap of the corresponding control unit, the top plate is spaced apart from the top surfaces of the two cantilever beam structures, the top plate is provided with a second flow channel port penetrating through the top plate, and the second flow channel port corresponds to the control unit.

As an improvement, in a same control unit, the two cantilever beam structures share a same initial phase of vibration and a same frequency of vibration.

As an improvement, a distance between a center of the second flow channel port and the second end of the cantilever beam structure directly facing the second flow channel port is within a range from 100 μm to 5000 μm.

As an improvement, a height of at least one of the two anchor structures is within a range from 100 μm to 5000 μm.

As an improvement, in an arrangement direction of the two anchor structures, a width of the first flow channel port is greater than or equal to a width of the second gap.

As an improvement, in the arrangement direction of the two anchor structures, a width of the second flow channel port is smaller than the width of the second gap, and a spacing between the top plate and at least one of the two cantilever beam structures is smaller than a spacing between the bottom plate and the at least one of the two cantilever beam structures.

As an improvement, in a same control unit, the first flow channel port directly faces the second gap.

As an improvement, the at least one control unit includes two or more control units, and each second flow channel port directly faces the cantilever beam structure at a same side of each of the two or more control units along an arrangement direction of the two anchor structures.

As an improvement, the at least one control unit includes two or more control units, and two adjacent second flow channel ports directly face the cantilever beam structures at different sides of the two or more control units along an arrangement direction of the two anchor structures.

In an aspect, an embodiment of the present disclosure provides a MEMS device, including the MEMS controller described above.

The technical solutions provided by the embodiments of the present disclosure have at least the following advantages. When the MEMS device is used as a part of a heat dispersing device, the second end of the cantilever beam structure vibrates to suck cooling fluid from one of the first flow channel port or the second flow channel port, and then the fluid flows through the gap between the cantilever beam structures and flows out from the other one of the first flow channel port or the second flow channel port, thereby achieving unidirectional flowing control of the gas. When the MEMS device is used as a part of a speaker, the second end of the cantilever beam structure vibrates to generate a high-frequency signal, and a sound channel surrounded by the encapsulation structure, the cantilever beam structure, and the anchor structure can achieve the demodulation of the high-frequency signal, thereby converting the high-frequency signal to be a low-frequency signal, to output a human-audible sound frequency. The encapsulation structure serves as a protective shell of the control unit and encloses the control unit to form a flow channel, thereby facilitating the output of the cooling fluid or the demodulation of the sound.

### BRIEF DESCRIPTION OF DRAWINGS

One or more embodiments are exemplarily illustrated by the corresponding figures in the accompanying drawings, but are not intended to limit the present disclosure. Unless otherwise specified, the figures in the accompanying drawings do not indicate a scale limit. To better illustrate the technical solutions in the embodiments of the present disclosure or in the conventional technical means, a brief introduction to the accompanying drawings required in the embodiments will be provided below. It should be noted that the accompanying drawings described below are merely some embodiments of the present disclosure. For those skilled in the art, other drawings may be obtained based on these accompanying drawings without any creative efforts.

FIG. 1 is a schematic diagram of a structure of a MEMS controller according to an embodiment of the present disclosure;

FIG. 2 is a curve diagram of a relationship between a height of an anchor structure and a flow rate per unit chip volume according to an embodiment of the present disclosure;

FIG. 3 is a diagram of a relationship between a first distance and a flow rate per unit chip volume according to an embodiment of the present disclosure;

FIG. 4 is an arrangement of a control unit according to an embodiment of the present disclosure;

FIG. 5 is another arrangement of a control unit according to an embodiment of the present disclosure;

FIG. 6 is another arrangement of a control unit according to an embodiment of the present disclosure;

FIG. 7 is a schematic diagram of a structure of a first flow channel port as a flow outlet;

FIG. 8 is a schematic diagram of a structure of a second flow channel port as a flow outlet;

FIG. 9 is a time domain diagram of a displacement of a second end of a cantilever beam structure;

FIG. 10 is a time domain diagram of a flow rate of a fluid flowing out through a second flow channel port;

FIG. 11 is a schematic diagram of a structure of a second flow channel port as a sound outlet;

FIG. 12 is a schematic diagram of a structure of a first flow channel port as a sound outlet;

FIG. 13 is a spectrum diagram of an ultrasonic signal generated by a cantilever beam structure;

FIG. 14 is a spectrum diagram of a sound pressure at the sound outlet; and

FIG. 15 is a schematic diagram of a simulated structure of a loudspeaking process.

### DETAILED DESCRIPTION OF EMBODIMENTS

F As can be known from the background technology, it is currently necessary to provide a MEMS controller to control the unidirectional flow of a fluid.

An embodiment of the present disclosure provides a MEMS controller and a MEMS device. When the MEMS device is used as a part of a heat dispersing device, the second end of the cantilever beam structure vibrates to suck cooling fluid from one of the first flow channel port or the second flow channel port, and then the fluid flows through the gap between the cantilever beam structures and flows out from the other one of the first flow channel port or the second flow channel port, thereby achieving unidirectional flowing control of the gas. When the MEMS device is used as a part of a speaker, the second end of the cantilever beam structure vibrates to generate a high-frequency signal, and a sound channel surrounded by the encapsulation structure, the cantilever beam structure, and the anchor structure can achieve the demodulation of the high-frequency signal, thereby converting the high-frequency signal to be a low-frequency signal, to output a human-audible sound frequency. The encapsulation structure serves as a protective shell of the control unit and encloses the control unit to form a flow channel, thereby facilitating the output of the cooling fluid or the demodulation of the sound.

In the description of the embodiments of the present disclosure, the technical terms “first”, “second”, etc. are only used to distinguish different objects, and cannot be understood as indicating or implying relative importance or implicitly indicating the number, specific order or primary and secondary relationship of the indicated technical features. In the description of the embodiments of the present disclosure, the meaning of “multiple/a plurality of” refers to more than two, unless otherwise clearly and specifically defined.

Reference to “embodiments” herein means that a particular feature, structure, or characteristic described in conjunction with the embodiments may be included in at least one embodiment of the present disclosure. The appearance of this phrase in various places in the specification does not necessarily refer to a same embodiment, nor is it an independent or alternative embodiment that is mutually exclusive with other embodiments. It is explicitly and implicitly understood by those skilled in the art that an embodiment described herein may be combined with other embodiment.

In the description of the embodiments of the present disclosure, the term “and/or” is only a description of the association relationship of associated objects, indicating that three relationships may exist. For example, A and/or B may represent: A exists alone, A and B exist at the same time, and B exists alone. In addition, the character “/” in the specification generally indicates that the associated objects prior to and subsequent to the character “/” are in an “or” relationship.

In the description of the embodiments of the present disclosure, the term “multiple/a plurality of” refers to more than two (including two). Similarly, “multiple/a plurality of groups” refers to more than two groups (including two groups), and “multiple/a plurality of pieces” refers to more than two pieces (including two pieces).

In the description of the embodiments of the present disclosure, the technical terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, and the like indicate orientations or positions based on the orientations or positions shown in the accompanying drawings, which are just to facilitate describing the embodiments of the present disclosure and simplifying the description, and do not indicate or imply that the referred device or element must have a specific orientation, be constructed and operated in a specific orientation, and therefore should not be understood as limiting the embodiments of the present disclosure.

In the description of the embodiments of the present disclosure, unless otherwise clearly specified and limited, technical terms such as “installation”, “coupling”, “connection”, “fixation” and the like should be understood in a broad sense, for example, it can be a fixed connection, a detachable connection, or an integral connection; it can be a mechanical connection or an electrical connection; it can be a direct connection or an indirect connection through an intermediate medium; it can be an internal connection of two elements or an interaction relationship between two elements. For ordinary skilled in the art, the specific meanings of the above-mentioned terms in the embodiments of the present disclosure can be understood according to specific circumstances.

In the accompanying drawings corresponding to the embodiments of the present disclosure, a thickness and an area of a layer is exaggerated for better illustration and ease of description. When describing one component (such as a layer, a film, a region or a lens body) at another one component or at a surface of another one component, the one component may be “directly” located at the surface of said another one component, or a third component may also exist between the two components. On the contrary, when describing one component on a surface of another one component or when another one component is formed or provided on a surface of one component, it means that there is no third component between the two components. In addition, when describing one component “substantially” formed at another one component, it means that the one component is not formed at an entire surface (or a front surface) of said another one component, nor is it formed at a partial edge of the entire surface.

In the description of the embodiments of the present disclosure, when describing that one component “includes” another one component, unless otherwise specified, other components are not excluded, and other components may be further included. In addition, when describing that one component such as a layer, film, region, or plate is located at/on another one component, the one component can be “directly located at” the another one component (i.e., located on a surface of the another one component without other components therebetween), or another component may exist therebetween. In addition, when describing that one component such as a layer, film, region, or plate is “directly located at” another one component, or when describing that one component such as a layer, film, region, or plate is located on a surface of another one component, it means that no other components are located therebetween.

The terms used in the description of the various embodiments described herein are only used to describe specific embodiments and are not intended to limit thereto. As used in the description of the various embodiments described herein and in the appended claims, “the component” is also intended to include plural forms unless the context clearly indicates otherwise. Herein, the component may include a component such as a layer, a film, a region, or a plate.

The following will describe the various embodiments of the present disclosure in detail with reference to the accompanying drawings. However, it will be appreciated by those skilled in the art that, in the various embodiments of the present disclosure, many technical details are provided in order to enable the reader to better understand the present disclosure. However, even without these technical details and various changes and modifications based on the following embodiments, the technical solutions claimed in the present disclosure can be implemented.

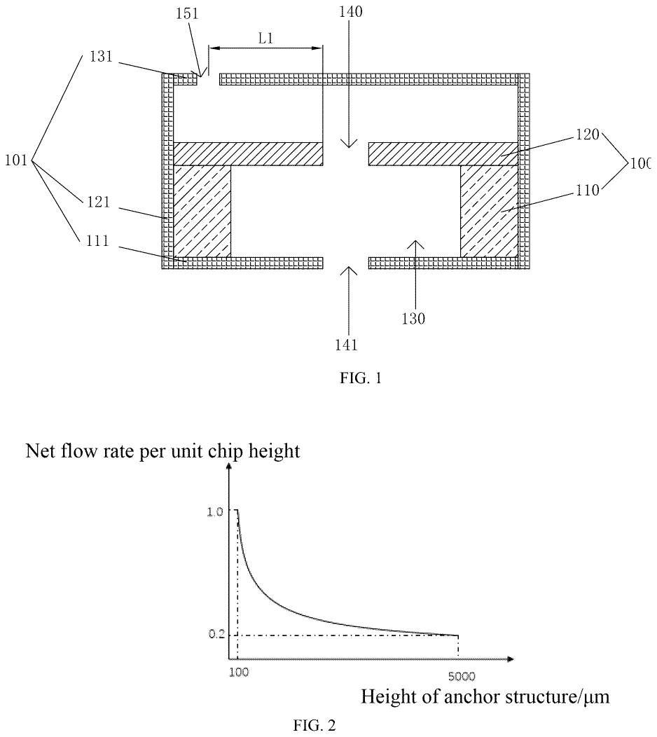

FIG. 1 is a schematic diagram of a structure of a MEMS controller according to an embodiment of the present disclosure.

In some embodiments, the MEMS controller may include: at least one control unit 100. The control unit 100 includes: two anchor structures 110, a first gap 130 being formed between the two anchor structures 110, and each of the two anchor structures 110 including a bottom surface and a top surface opposite to each other; and two cantilever beam structures 120 respectively corresponding to the two anchor structures 110, each of the two cantilever beam structure 120 including a first end and a second end opposite to each other, and the first end of each of the two cantilever beam structures 120 being located at a top surface of a corresponding anchor structure 110, and the second ends of the two cantilever beam structures 120 of one control unit 100 facing each other and forming a second gap 140 therebetween.

The MEMS controller may further include an encapsulation structure 101. The encapsulation structure 101 includes a bottom plate 111, a side plate 121 and a top plate 131 connected in sequence, the bottom plate 111 directly faces the top plate 131, and the side plate 121 connects the bottom plate 111 and the top plate 131. The bottom plate 111 is located at a bottom surface of the anchor structure 110, and a first flow channel port 141 penetrating through the bottom plate 111 is formed in the bottom plate 111. The first flow channel port 141 corresponds to the control unit 100, and the first flow channel port 141 is in communication with the first gap 130 of the corresponding control unit 100. The top plate 131 is spaced apart from a top surface of the cantilever beam structure 120. A second flow channel port 151 penetrating through the top plate 131 is formed in the top plate 131, and the second flow channel port 151 corresponds to the control unit 100.

For the MEMS device according to some embodiments of the present disclosure: when the MEMS device is used as a part of a heat dispersing device, the second end of the cantilever beam structure 120 vibrates to suck cooling fluid from one of the first flow channel port 141 or the second flow channel port 151, and then the fluid flows through the gap between the cantilever beam structures 120 and flows out from the other one of the first flow channel port 141 or the second flow channel port 151, thereby achieving unidirectional flowing control of the gas. When the MEMS device is used as a part of a speaker, the second end of the cantilever beam structure 120 vibrates to generate a high-frequency signal, and a sound channel surrounded by the encapsulation structure 101, the cantilever beam structure 120, and the anchor structure 110 can achieve the demodulation of the high-frequency signal, thereby converting the high-frequency signal to be a low-frequency signal, to output a human-audible sound frequency. The encapsulation structure 101 serves as a protective shell of the control unit 100 and encloses the control unit 100 to form a flow channel, thereby facilitating the output of the cooling fluid or the demodulation of the sound.

The anchor structure 110 can be used to support the cantilever beam structure 120. The top surface of the anchor structure 110 is fixedly connected to the first end of the cantilever beam structure 120. A driving signal can be provided to the cantilever beam structure 120 through the anchor structure 110. For example, when the MEMS controller needs to work, a driving signal can be provided to the cantilever beam structure 120 through the anchor structure 110 to drive the cantilever beam structure 120 to vibrate.

The anchor structure 110 may drive the cantilever beam structure 120 in a manner including: piezoelectric driving, electrostatic driving, thermoelectric driving, electromagnetic driving, or the like. Taking piezoelectric driving as an example, an inverse piezoelectric effect of a piezoelectric material is used to convert electrical energy to be mechanical energy to drive the cantilever beam structure 120 to vibrate.

In some embodiments, the anchor structure 110 may be a control layer of a Silicon-On-Insulator (SOI) chip. The anchor structure 110 may also be a control layer of other types of chips that cooperate to drive the cantilever beam structure 120.

In some embodiments, during the operation of the MEMS controller, one of the two anchor structures 110 can be selected to control the vibration of the corresponding cantilever beam structure 120, or two anchor structures 110 can control the vibration of the cantilever beam structures 120. The operation time or operation state of the anchor structure 110 can be selected according to different operation requirements.

In some embodiments, the height of the anchor structure 150 is within a range from 100 μm to 5000 μm, for example, 300 μm, 500 μm, 1000 μm, 1800 μm, 2500 μm, 3000 μm, 4000 μm or 4600 μm, etc. Referring to FIG. 2, which is a curve diagram of a relationship between a height of an anchor structure and a flow rate per unit chip volume according to an embodiment of the present disclosure, for the anchor structure 110, the height of the anchor structure 110 is positively correlated with a net flow rate of the fluid driven by the MEMS controller. That is, the higher the height of the anchor structure 110 is, the greater the net flow rate of the fluid that can pass through the MEMS controller is. However, the higher the height of the anchor structure 110 is, the larger the size of the entire MEMS controller is. Further, the higher the height of the anchor structure 110 is, the less a net flow rate per unit chip volume is, resulting in performance waste of the anchor structure 110. Furthermore, the lower the height of the anchor structure 110 is, although the net flow rate of the fluid that can pass through the MEMS controller may decrease, the greater the net flow rate per unit chip volume is, that is, the performance utilization rate of the anchor structure 110 may increase. Similarly, as the height of the anchor structure 110 decreases, the difficulty of the formation process of the MEMS controller may increase. Therefore, the height of the anchor structure 110 is set to be within a range from 100 μm to 5000 μm, which improves the net flow rate per unit chip volume while taking into account the process difficulty for forming the MEMS controller.

It should be noted that the flow rate per unit chip volume here refers to: a total flow rate of the fluid output through the MEMS controller per unit time divided by a planar area of the MEMS controller.

The vibration frequency of the cantilever beam structure 120 is greater than or equal to 20 KHz, such as 30 KHz, 50 KHz or 100 KHz, etc. The vibration frequency of the cantilever beam structure 120 is greater than or equal to 20 KHz, which can increase the flowing rate of the fluid flowing in or out through the first flow channel port 141.

In some embodiments, the cantilever beam structures 120 in a same control unit 100 may correspond to a same initial phase of vibration and a same frequency of vibration (i.e., vibration frequency). By controlling the cantilever beam structures 120 in the same control unit 100 to correspond to a same initial phase of vibration and a same frequency vibration, interference between the cantilever beam structures 120 in the same control unit 100 can be avoided. For example, when the MEMS controller requires unidirectional flowing of the gas, it can be avoided that one cantilever beam structure 120 in the same control unit 100 controls the gas to enter from the first flow channel port 141 and exit from the second flow channel port 151, while the other one cantilever beam structure 120 in the same control unit 100 controls the gas to enter from the second flow channel port 151 and exit from the first flow channel port 141, thereby avoiding mutual interference between the cantilever beam structures 120 in the same control unit 100 and improving the stability of fluid control. Moreover, the cantilever beam structures 120 in the same control unit 100 is controlled to share a same initial phase of vibration and a same frequency of vibration, thereby facilitating the control of the MEMS controller and reducing the control difficulty.

In some embodiments, the cantilever beam structures 120 in a same control unit 100 may correspond to different initial phases of vibration, for example, with a difference of 10° or 20°, etc. By controlling the cantilever beam structures 120 in the same control unit 100 to correspond to different initial phases of vibration, the flowing rate of the fluid can be controlled. For example, when the flowing rate of the fluid needs to be adjusted, the initial phases of vibration of the cantilever beam structures 120 in the same control unit 100 can be changed to change the flowing rate of the fluid.

The encapsulation structure 101 can be used to protect the control unit 100, to lead out signals, or to transmit control signals to the control unit 100, thereby completing signal transmission. The encapsulation structure 101 can also be used to form a flow channel of the fluid, for example, to form a flow channel of the gas, to control the gas to enter from the first flow channel port 141 and exit from the second flow channel port 151, or to control the gas to enter from the second flow channel port 151 and exit from the first flow channel port 141.

In some embodiments, the encapsulation structure 101 may be a metal plate or a PCB, etc.

In some embodiments, the second flow channel port 151 directly faces a cantilever beam structure 120 of a corresponding control unit 100, and the second flow channel port 151 and the first flow channel port 141 are not aligned with each other. In some other embodiments, the second flow channel port 151 and a cantilever beam structure 120 of a corresponding control unit 100 are not aligned with each other and directly face the second gap 140, and the second flow channel port 151 and the first flow channel port 141 directly face each other.

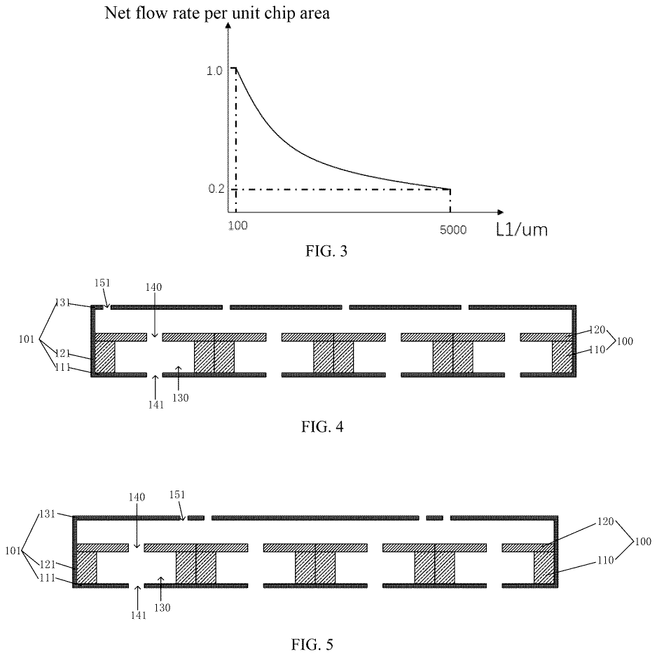

In some embodiments, a distance between a center of the second flow channel port 151 and a second end of the cantilever beam structure 120 directly facing the second flow channel port 151 is within a range from 100 μm to 5000 μm. The distance between the center of the second flow channel port 151 and the second end of the cantilever beam structure 120 directly facing the second flow channel port 151 is defined as a first distance L1. Referring to FIG. 3, which is a diagram of a relationship between a first distance and a flow rate per unit chip volume according to an embodiment of the present disclosure, for the MEMS controller, the first distance L1 is positively correlated with a net flow rate of the fluid driven by the MEMS controller. That is, the larger the first distance L1 is, the greater the net flow rate of the fluid that can pass through the MEMS controller is. However, the larger the first distance L1 is, the larger the size of the entire MEMS controller is. Further, the larger the first distance L1 is, the less the net flow rate per unit chip volume is, resulting in a waste of the performance of the cantilever beam structure 120. Furthermore, the smaller the first distance L1 is, although the net flow rate of the fluid that can pass through the MEMS controller may decrease, the greater the net flow rate per unit chip volume, that is, the performance utilization rate of the cantilever beam structure 120 may increase. Similarly, as the first distance L1 decreases, the difficulty of the formation process of the MEMS controller may increase. Therefore, the first distance L1 is set to be within a range from 100 μm to 5000 μm, which can improve the net flow rate per unit chip volume while taking into account the process difficulty for forming the MEMS controller.

It should be noted that the center of the second flow channel port 151 mentioned herein may refer to ta geometric center of the second flow channel port 151. If the second flow channel port 151 is shaped as a circle, the center mentioned herein refers to a center of the circle. If the second flow channel port 151 is shaped as a square, the center mentioned herein refers to a symmetry center of the square.

In some embodiments, in an arrangement direction of the anchor structure 110, a width of the first flow channel port 141 is greater than or equal to a width of the second gap 140. That is, in a same control unit 100, the width of the first flow channel port 141 is greater than or equal to the spacing between the two cantilever beam structures 120, so that when the fluid enters from the second gap 140 and exits from the first flow channel port 141, the loss of the fluid can be decreased; and when the fluid enters from the first flow channel port 141 and exits from the second gap 140, the decrease of the size of the outlet can make the kinetic energy of the fluid increase, thereby improving the flowing rate of the fluid.

In some embodiments, a width of the second flow channel port 151 in the arrangement direction of the anchor structure 110 is smaller than a width of the second gap 140, and a distance between the top plate 131 and the cantilever beam structure 120 is smaller than a distance between the bottom plate 111 and the cantilever beam structure 120. The accommodation space directly related to the second flow channel port 151 is the space enclosed by the encapsulation structure 101 and the cantilever beam structure 120, and the accommodation space directly related to the first flow channel port 141 is the space enclosed by the encapsulation structure 101, the cantilever beam structure 120 and the anchor structure 110. When the width of the second flow channel port 151 is set to be small, the accommodation space directly related to the second flow channel port 151 is set to be small, so that no matter the fluid enters from the second flow channel port 151 and exits from the second gap 140, or the fluid enters from the second gap 140 and exits from the second flow channel port 151, the fluid will have a higher flowing speed when flowing out. When the first flow channel port 141 is set to be large, the accommodation space directly related to the first flow channel port 141 is set to be large, if the first flow channel port 141 is used as the outlet of the fluid, a coverage area when the fluid flows out can be increased, and if the first flow channel port 141 is used as an inlet of the fluid, the fluid flowing out after the gas passes through the second gap 140 and the second flow channel port 151 can have a better flowing rate.

In some embodiments, the first flow channel port 141 directly faces the second gap 140 in a same control unit 100. In this way, whether the fluid flows from the second gap 140 to the first flow channel port 141 or the fluid flows from the first flow channel port 141 to the second gap 140, the loss in the flowing process can be decreased, and the noise in the flowing process of the fluid can also be decreased, thereby improving the performance of the MEMS controller.

FIG. 4 is an arrangement of a control unit according to an embodiment of the present disclosure. Referring to FIG. 4, in some embodiments, the number of control units 100 is greater than or equal to 2, and each second flow channel port 151 directly faces the cantilever beam structure 120 at a same side of each control unit 100 along an arrangement direction of the anchor structure 110. In other words, a position of the second flow channel port 151 corresponding to each control unit 100 is the same. For example, each second flow channel port 151 directly faces the cantilever beam structure 120 at a left side of the control unit 100. By controlling each second flow channel port 151 to directly face the cantilever beam structure 120 at a same side of each control unit 100 along the arrangement direction of the anchor structure 110, the process difficulty for forming the MEMS controller can be decreased.

FIG. 5 is another arrangement of a control unit according to an embodiment of the present disclosure. FIG. 6 is another arrangement of a control unit according to an embodiment of the present disclosure.

In some embodiments, the number of control units 100 is greater than or equal to 2, and two adjacent second flow channel ports 151 directly face the cantilever beam structures 120 at different sides of the control units 100 along the arrangement direction of the anchor structure 110. In other words, the positions of the second flow channel ports 151 corresponding to different control units 100 are different, for example, one of two adjacent second flow channel ports 151 directly faces the cantilever beam structure 120 at a left side of the control unit 100, and the other one of the two adjacent second flow channel ports 151 directly faces the cantilever beam structure 120 at a right side of the control unit 100. For a MEMS controller including multiple control units 100, two adjacent second flow channel ports 151 directly face the cantilever beam structures 120 at different sides of the control units 100 along the arrangement direction of the anchor structure 110, which can improve the control effect of the MEMS controller, for example, the reliability of the MEMS to control unidirectional flowing of the airflow, or the reliability of the reliability of the sound demodulation of the MEMS.

Referring to FIG. 5, in some embodiments, the number of control units 100 is greater than or equal to 2, and the second flow channel port 151 of the control unit 100 in contact with the side plate 121 directly faces the cantilever beam structure 120 away from the side plate 121, so that the inlet or outlet of the fluid can be set at a part of the MEMS controller close to a center, thereby improving the stress resistance of the encapsulation structure 101 and improving the reliability of the MEMS controller.

Referring to FIG. 6, in some embodiments, the number of control units 100 is greater than or equal to 2, and the second flow channel port 151 of the control unit 100 in contact with the side plate 121 directly faces the cantilever beam structure 120 close to the side plate 121, so that the inlet or outlet of the fluid can be set at different parts of the MEMS controller. For example, when the fluid flows out from the second flow channel port 151, the second flow channel port 151 is arranged to directly face the cantilever beam structure 120 close to the side plate 121, thereby avoiding a dead angle of the outflow of the fluid from the MEMS controller.

It should be noted that the above-mentioned dead angle refers to a part that cannot be covered after the fluid flows out.

In some embodiments, the cantilever beam structures 120 in different control units 100 may correspond to a same initial phase of vibration and a same frequency of vibration. In some other embodiments, the cantilever beam structures 120 in different control units 100 may correspond to different initial phases of vibration, different frequencies of vibration, and/or different amplitudes of vibration, and the vibration conditions of the cantilever beam structures 120 in different control units 100 may be adjusted according to actual requirements.

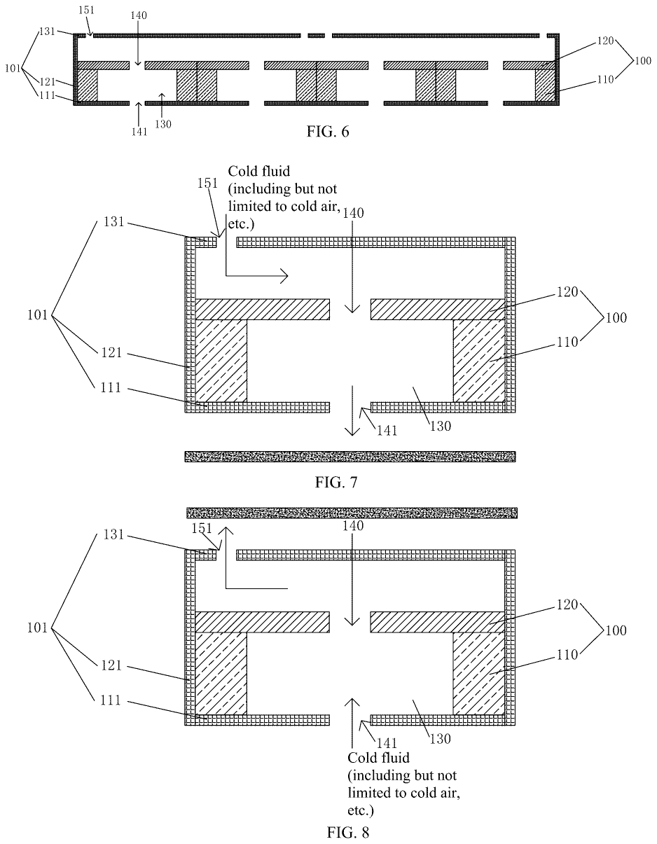

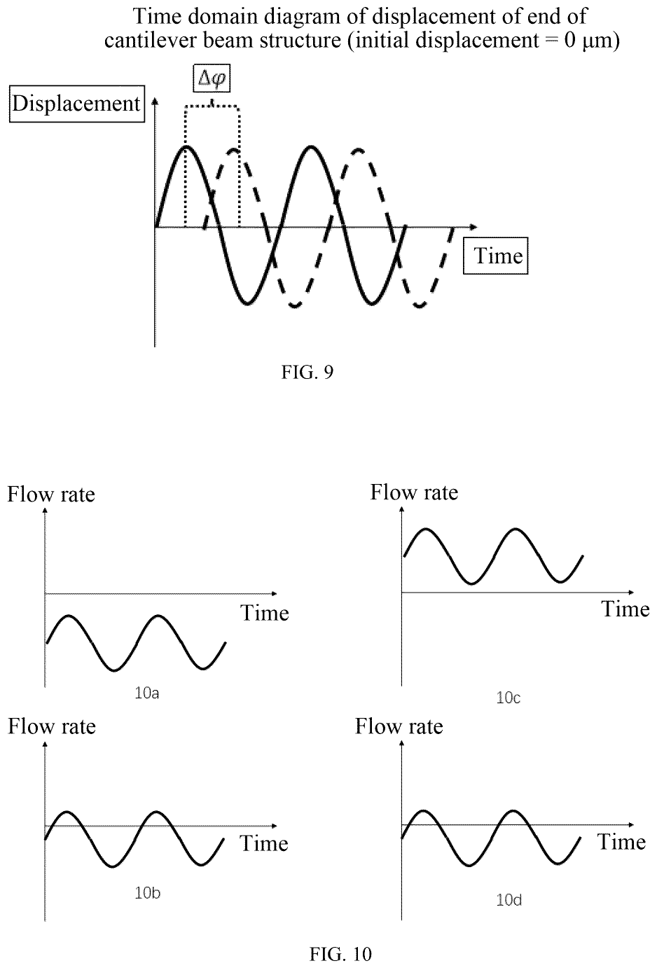

The following will describe in detail the working process of the MEMS controller when it performs heat dissipation in combination with FIG. 7 to FIG. 10. FIG. 7 is a schematic diagram of a structure of a first flow channel port as a flow outlet. FIG. 8 is a schematic diagram of a structure of a second flow channel port as a flow outlet. FIG. 9 is a time domain diagram of a displacement of a second end of a cantilever beam structure. FIG. 10 is a time domain diagram of a flow rate of a fluid flowing out through a second flow channel port.

Referring to FIG. 7, FIG. 9 and FIG. 10, when the MEMS controller needs to perform heat dissipation, the cantilever beam structure 120 is controlled to vibrate, and the cold fluid flows in from the second flow channel port 151, passes through the second gap 140 and the first gap 120 in sequence, and flows out from the first flow channel port 141. The first flow channel port 141 can directly face the structure that needs heat dissipation, so that the cold fluid hits a surface of the structure that needs heat dissipation to complete the heat dissipation and cooling process.

In some embodiments, in a same control unit 100, the vibration of one cantilever beam structure 120 satisfies: dₛ=d₁Sin(2πf₀t), and the vibration of another cantilever beam structure 120 satisfies: dₛ=d₁Sin(2πf₀t+Δφ), where d₁ represents an amplitude of the vibration of the cantilever beam structure 120, f₀ represents an operating frequency of the MEMS controller, and Δφ represents an initial phase difference between the vibrations of two cantilever beam structures 120 in the same control unit 100.

Referring to FIG. 10, when Δφ is equal to 0, the flow time domain diagram of the fluid flowing into the second flow channel port 151 may be as shown in FIG. 10a; and when Δφ is not equal to 0, the flow time domain diagram of the fluid flowing into the second flow channel port 151 may be as shown in FIG. 10b.

It should be noted that the above-mentioned definition of Δφ used to draw a flow time domain diagram of the fluid flowing into the second flow channel port 151 are merely for the purpose of ease of understanding. In some other embodiments, when Δφ is not equal to 0, the flow time domain diagram of the fluid flowing into the second flow channel port 151 may be as shown in FIG. 10 a; and when Δφ is equal to 0, the flow time domain diagram of the fluid flowing into the second flow channel port 151 may be as shown in FIG. 10b.

According to the embodiments of the present disclosure, the unidirectional flowing of the fluid can be controlled by the MEMS controller, and the speed of the fluid flowing into the second flow channel port 151 can be no less than 20 m/s.

Referring to FIG. 8, FIG. 9 and FIG. 10, when the MEMS controller needs heat dissipation, the cantilever beam structure is controlled to vibrate, and the cold fluid flows in from the first flow channel port, passes through the first gap and the second gap in sequence, and flows out through the second flow channel port. The second flow channel port may directly face the structure that needs heat dissipation, so that the cold fluid hits a surface of the structure that needs heat dissipation to complete the heat dissipation and cooling process.

In some embodiments, in a same control unit 100, the vibration of a cantilever beam structure 120 satisfies: dₛ=d₁Sin(2πf₀t), and the vibration of another cantilever beam structure 120 satisfies: dₛ=d₁Sin(2πf₀t+Δφ), where d₁ represents an amplitude of the vibration of the cantilever beam structure 120, f₀ represents an operating frequency of the MEMS controller, and Δφ represents an initial phase difference between the vibrations of two cantilever beam structures 120 in the same control unit 100.

Referring to FIG. 10, when Δφ is equal to 0, the flow time domain diagram of the fluid flowing out from the second flow channel port 151 may be as shown in FIG. 10c; and when Δφ is not equal to 0, the flow time domain diagram of the fluid flowing out from the second flow channel port 151 may be as shown in FIG. 10d.

It should be noted that the above-mentioned definition of Δφ used to draw a flow time domain diagram of the fluid flowing out from the second flow channel port 151 are merely for the purpose of ease of understanding. In some other embodiments, when Δφ is not equal to 0, the flow time domain diagram of the fluid flowing out from the second flow channel port 151 may be as shown in FIG. 10c; and when Δφ is equal to 0, the flow time domain diagram of the fluid flowing out from the second flow channel port 151 may be as shown in FIG. 10d.

According to some embodiments of the present disclosure, the unidirectional flowing of the fluid can be controlled by the MEMS controller, and the speed of the fluid flowing into the second flow channel port 151 can be no less than 20 m/s.

The present disclosure does not limit the fluid. The fluid may be liquid, gas, or sound wave, etc.

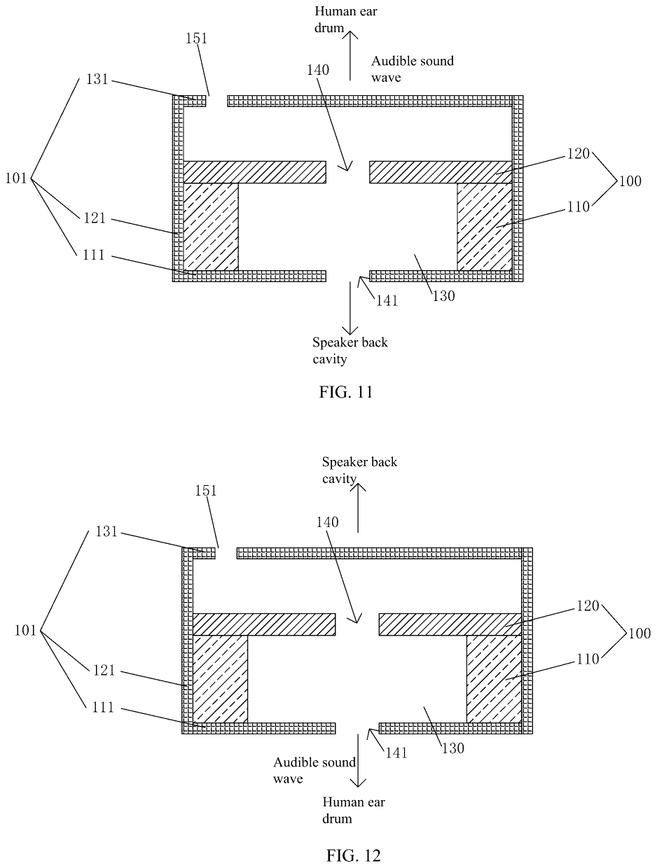

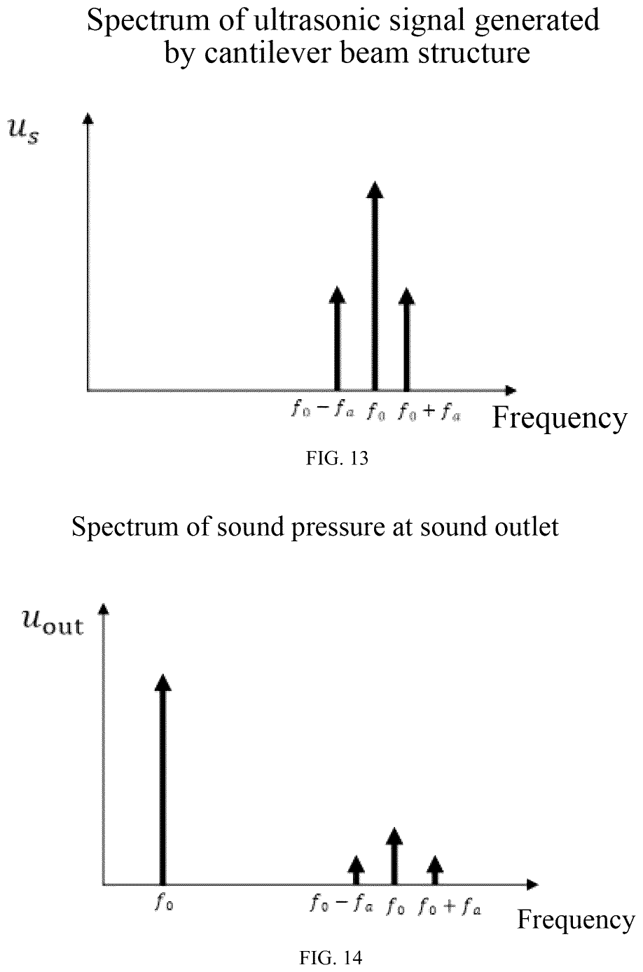

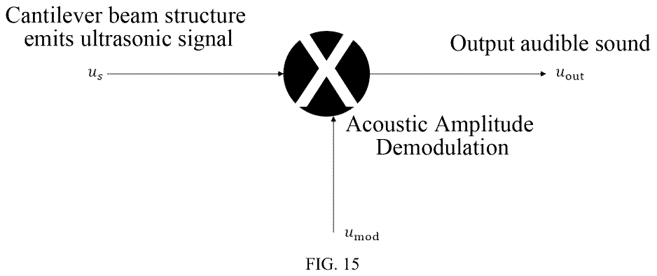

The following will describe in detail the working process of the MEMS controller when it performs sound loudspeaking in combination with FIG. 11 to FIG. 15. FIG. 11 is a schematic diagram of a structure of a second flow channel port as a sound outlet. FIG. 12 is a schematic diagram of a structure of a first flow channel port as a sound outlet. FIG. 13 is a spectrum diagram of an ultrasonic signal generated by a cantilever beam structure. FIG. 14 is a spectrum diagram of a sound pressure at the sound outlet. FIG. 15 is a schematic diagram of a simulation structure of a loudspeaking process.

When the sound loudspeaking needs to be performed, the driving signal generated by the anchor structure 110 drives the cantilever beam structure 120 at two sides to move, and the displacement satisfies: dₛ=d₁Sin(2πf₀t)Sin(2πfₐt), where d₁ represents an amplitude of the vibration of the cantilever beam structure 120, f₀ represents the ultrasonic frequency, and fₐ represents an audible sound frequency. After the cantilever beam structure 120 vibrates, ultrasound will be formed, and the spectrum signal is shown in FIG. 13. The sound pressure of the ultrasound satisfies: uₛ=u₁Sin(2πf₀t)Sin(2πfₐt), where u₁ represents the amplitude of the sound pressure. The sound channel formed by the present disclosure will perform demodulation of the sound, i.e., amplitude modulation, and the amplitude modulation satisfies: u_{mod}=u₂Sin(2πf₀t), where u₂ represents an amplitude of the sound pressure. When the ultrasonic signal uₛ is modulated by the amplitude of the sound channel, an output sound pressure uₒᵤₜ is formed, and the output sound pressure satisfies: uₒᵤₜ₌u_{sX}u_{mod=}u₁Sin(2πf₀t)Sin(2πfₐt)×u₂Sin(2πf₀t), where ×represents a multiplication symbol, and the audible sound frequency fₐ can be obtained. The spectrum diagram of the output sound pressure is shown in FIG. 14.

The MEMS according to the present disclosure can demodulate sound when used for sound loudspeaking, thereby converting an ultrasonic frequency to be a human-audible sound frequency.

Another embodiment of the present disclosure further provides a MEMS device, which may include the MEMS controller according to some or all of the above embodiments. The MEMS device according to another embodiment of the present disclosure will be described below. It should be noted that the same or corresponding parts of the above embodiments may refer to the corresponding descriptions therein and will not be repeated below.

The MEMS device provided by the present disclosure can be used for heat dissipation or sound loudspeaking.

It can be understood by those skilled in the art that the above-mentioned embodiments are specific embodiments of the present disclosure, and in practical applications, various changes can be made in form and detail without departing from a spirit and a scope of the embodiments of the present disclosure. Any person skilled in the art can make various changes and modifications without departing from a spirit and a scope of the embodiments of the present disclosure, so a protection scope of the embodiments of the present disclosure shall be defined by the attached claims.

What is claimed is:

1. A Micro-Electro-Mechanical System (MEMS) controller, comprising:
at least one control unit, wherein one of the at least one control unit comprises:
two anchor structures, a first gap being formed between the two adjacent anchor structures, and each of the two anchor structures comprising a bottom surface and a top surface opposite to each other; and
two cantilever beam structures respectively corresponding to the two anchor structures, each of the two cantilever beam structures comprising a first end and a second end opposite to each other, the first end of each of the two cantilever beam structures being located at the top surface of the anchor structure corresponding thereto, and the second ends of the two cantilever beam structures in one control unit directly facing each other and forming a second gap therebetween; and
an encapsulation structure comprising a bottom plate, a side plate and a top plate connected in sequence, the bottom plate facing the top plate, and the side plate connecting the bottom plate and the top plate,
wherein the bottom plate is located at the bottom surfaces of the two anchor structures, the bottom plate is provided with a first flow channel port penetrating through the bottom plate, the first flow channel port corresponds to the control unit, the first flow channel port is in communication with the first gap of the control unit corresponding thereto, the top plate is spaced apart from top surfaces of the two cantilever beam structures, the top plate is provided with a second flow channel port penetrating through the top plate, and the second flow channel port corresponds to the control unit.

2. The MEMS controller as described in claim 1, wherein in a same control unit, the two cantilever beam structures share a same initial phase of vibration and a same frequency of vibration.

3. The MEMS controller as described in claim 1, wherein a distance between a center of the second flow channel port and a second end of a cantilever beam structure directly facing the second flow channel port is within a range from 100 μm to 5000 μm.

4. The MEMS controller as described in claim 1, wherein a height of at least one of the two anchor structures is within a range from 100 μm to 5000 μm.

5. The MEMS controller as described in claim 1, wherein in an arrangement direction of the two anchor structures, a width of the first flow channel port is greater than or equal to a width of the second gap.

6. The MEMS controller as described in claim 5, wherein in the arrangement direction of the two anchor structures, a width of the second flow channel port is smaller than the width of the second gap, and a spacing between the top plate and at least one of the two cantilever beam structures is smaller than a spacing between the bottom plate and the at least one of the two cantilever beam structures.

7. The MEMS controller as described in claim 1, wherein in a same control unit, the first flow channel port directly faces the second gap.

8. The MEMS controller as described in claim 1, wherein the at least one control unit comprises two or more control units, and each second flow channel port directly faces a cantilever beam structure at a same side of each of the two or more control units along an arrangement direction of the two anchor structures.

9. The MEMS controller as described in claim 1, wherein the at least one control unit comprises two or more control units, and two adjacent second flow channel ports directly face cantilever beam structures at different sides of the two or more control units along an arrangement direction of the two anchor structures.

10. A MEMS device, comprising the MEMS controller as described in claim 1.
